(19) United States
(12) Patent Application Publication
(10) Pub. No.: US 2026/0099096 A1
(43) Pub. Date: Apr. 9, 2026

(54) BATCH PROCESSING TOOL FOR DRY DEVELOP OF EXTREME ULTRA VIOLET (EUV) RESIST LAYER

(71) Applicant: Applied Materials, Inc., Santa Clara, CA (US)

(72) Inventors: NASRIN KAZEM, Santa Clara, CA (US); RUDY WOJTECKI, East Garrison, CA (US)

(21) Appl. No.: 19/329,445

(22) Filed: Sep. 15, 2025

Related U.S. Application Data
(60) Provisional application No. 63/704,365, filed on Oct. 7, 2024.

(51) Int. Cl. G03F 7/36; G03F 7/004; G03F 7/20; G03F 7/38

(52) U.S. Cl. CPC G03F 7/36; G03F 7/0045; G03F 7/203; G03F 7/38

(57) ABSTRACT

Embodiments described herein relate to a method of developing a resist layer on a substrate that has been selectively exposed with a lithography process. In an embodiment the method includes exposing the resist layer to a gas including one or both of an organic acid or a ketone in a chamber with an exposure time that is at least ten minutes, where the gas selectively removes an unexposed portion of the resist layer to form a pattern in the resist layer, and where the resist layer includes a metal. The method may further include purging the chamber.

### CROSS-REFERENCE TO RELATED APPLICATIONS

This application claims the benefit of U.S. Provisional Application No. 63/704,365, filed on Oct. 7, 2024, the entire contents of which are hereby incorporated by reference herein.

### BACKGROUND

### 1) Field

Embodiments relate to the field of semiconductor manufacturing and, in particular, dry development processes for extreme ultra violet (EUV) photoresist layers using a batch processing chamber.

### 2) Description of Related Art

Extreme ultraviolet (EUV) photoresists allow for the continued scaling to smaller features that are patterned on a semiconductor substrate. In an EUV lithography process, EUV radiation is selectively applied to regions of the photoresist layer in order to generate a solubility switch that enables the formation of a latent image within the photoresist layer. The latent image corresponds to the portions of the photoresist layer that have undergone the solubility switch as a result of a chemical reaction that is induced by the EUV exposure. After the latent image is produced within the photoresist layer, a developing process may be used in order to generate a pattern in the photoresist layer. Due to the small feature sizes of the structures within the pattern (e.g., trenches, holes, lines, etc.), special care with respect to line edge roughness (LER), resolution, etc. is necessary in order to provide optimal pattern transfer into underlying layers. Such pattern characteristics may be impacted by the type of development process and/or the specific chemistries that are used during the development process.

### SUMMARY

Embodiments described herein relate to a method of developing a resist layer on a substrate that has been selectively exposed with a lithography process. In an embodiment the method includes exposing the resist layer to a gas including one or both of an organic acid or a ketone in a chamber with an exposure time that is at least ten minutes, where the gas selectively removes an unexposed portion of the resist layer to form a pattern in the resist layer, and where the resist layer includes a metal. The method may further include purging the chamber.

Embodiments described herein relate to a method that includes rotating a substrate through a chamber including a first region and a second region, where the substrate includes a resist layer with a latent image produced by exposure to extreme ultraviolet (EUV) radiation. The method may further include exposing the resist layer to a processing gas that includes an organic acid and/or a ketone in the first region of the chamber, and exposing the resist layer to an inert gas in the second region of the chamber.

Embodiments described herein relate to a tool that includes a chamber for supporting a sub-atmospheric pressure, and a stage that is rotatable within the chamber, where the stage is sized to retain a plurality of substrates. In an embodiment, a first region of the chamber is used for treating the plurality of substrates with a processing gas for resist development, and a second region of the chamber is used for exposing the plurality of substrates to an inert gas. In an embodiment, a separator between the first region and the second region is configured to substantially retain the processing gas within the first region. region.

[symbol]

### BRIEF DESCRIPTION OF THE DRAWINGS

FIG. 1A-1D are cross-sectional illustrations that depict a process for patterning a resist layer with a dry development process, in accordance with an embodiment.

FIG. 2A is a flow diagram that depicts a process for developing a resist layer with an organic acid dry develop process, in accordance with an embodiment.

FIG. 2B is a flow diagram that depicts a process for developing a resist layer with a fluorination treatment and/or a sulfurization treatment and an organic acid dry develop process, in accordance with an embodiment.

FIG. 3 is a plan view schematic illustration of a processing tool with a plurality of chambers for developing a resist with a dry develop process, in accordance with an embodiment.

FIG. 4A is a perspective view of a stage for supporting and rotating substrates within a chamber of a resist dry develop chamber, in accordance with an embodiment.

FIG. 4B is a plan view illustration of a stage for supporting and rotating substrates between a first region and a second region of a resist dry develop chamber, in accordance with an embodiment.

FIG. 5A is a plan view illustration of a stage for supporting and rotating substrates between a first region and a second region of a resist dry develop chamber, in accordance with an embodiment.

FIG. 5B is a cross-sectional illustration of the resist dry develop chamber that illustrates a gas curtain between the first region and the second region, in accordance with an embodiment.

FIG. 5C is a plan view illustration of a stage for supporting and rotating substrates between a first region and a second region of a resist dry develop chamber, in accordance with an additional embodiment.

FIG. 5D is a plan view illustration of a stage for supporting and rotating substrates between a first region and a second region of a resist dry develop chamber, in accordance with yet another embodiment.

FIG. 5E is a plan view illustration of a stage for supporting and rotating substrates between a first region, a second region, and a third region of a resist dry develop chamber, in accordance with an embodiment.

FIG. 6 is a perspective view illustration of a portion of a batch oven for implementing a post exposure bake (PEB) of a plurality of substrates before developing, in accordance with an embodiment.

FIG. 7 is a cross-sectional schematic illustration of a batch chamber for developing the resist layer of a plurality of stacked substrates with a dry develop process, in accordance with an embodiment.

FIG. 8 is a cross-sectional schematic illustration of a post development treatment chamber to modify the structure of the resist layer after the resist layer is patterned, in accordance with an embodiment.

FIG. 9 illustrates a block diagram of an exemplary computer system that may be used in conjunction with a processing tool, in accordance with an embodiment.

### DETAILED DESCRIPTION

Embodiments described herein include a batch processing tool for implementing dry development of an exposed extreme ultraviolet (EUV) resist layer with an acetic acid soak. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, careful care in the design of EUV photoresist materials is necessary in order to provide optimal patterning metrics, such a low line edge roughness (LER), and/or good resolution. Limitations in the etch resistance of the EUV photoresist also leads to the need for thicker photoresist materials. When thicker resist layers are used, the patterns formed within the EUV photoresist are more prone to pattern collapse. That is, adjacent lines may tilt and/or bend so that neighboring lines touch each other. This can lead to significant patterning defects.

Accordingly, embodiments disclosed herein include EUV resist materials and patterning processes that are designed to improved patterning metrics and prevent pattern collapse and/or other patterning defects. In a particular embodiment, the EUV resist material may comprise a metal oxide resist (MOR) material. The MOR material may also include an organometallic oxide material. In an embodiment a MOR material may comprise a photoresist material with one or more metals (e.g., tin, indium, hafnium, zinc, zirconium, or any combination thereof). The MOR material may also comprise an organotin-oxo photoresist material, an organoindium-oxo photoresist material, or the like.

In an embodiment, the pattern formed into the MOR layer may be formed with an exposure to radiation of a particular wavelength or wavelengths. For example, deep ultraviolet (DUV) radiation, extreme ultraviolet (EUV) radiation, or the like may be used to initiate a solubility switch within the MOR layer. The exposure may be made through a mask, a reticle, or the like. The MOR layer may also be exposed through a laser exposure, electron beam exposure, or the like.

In an embodiment, the MOR layer includes a latent image that matches the radiation pattern used to expose the MOR layer. The latent image may then be developed with a developing process. In a particular embodiment, the developing process may be a dry develop process. For example, a dry etching process may be used to remove portions of the MOR layer (e.g., either the latent image or the unexposed regions, depending on the tone of the MOR layer). The use of a dry process reduces the probability of pattern collapse and improves LER compared to wet etching processes. For example, wet etching processes will generate capillary forces from the wet etchant. Spinning the substrate during drying may also induce forces on the MOR layer. These additional forces may bend and/or tip over lines in the MOR layer, and/or negatively impact the LER.

In some embodiments, the dry develop process comprises the exposure to a processing gas that comprises an organic acid and/or a ketone. The MOR lay may be exposed to the organic acid for a relatively long exposure period (e.g., approximately 0.5 minutes or more, approximately 1.0 minutes or more, approximately 5.0 minutes or more, approximately 6.0 minutes or more, approximately 7.0 minutes or more, approximately 8.0 minutes or more, approximately 9.0 minutes or more, approximately 10 minutes or more, approximately 30 minutes or more, approximately 1.0 hours or more, or approximately 2.0 hours or more). In other embodiments, the dry develop process may also comprise a fluorination treatment before exposure to the organic acid. In an embodiment, the fluorination treatment and the organic acid soak may be cycled a plurality of times.

As can be appreciated, the dry developing process may be a bottleneck for the lithography throughput due to long exposure periods and/or the need for multiple cycles. Accordingly, embodiments disclosed herein may include a dry developing chamber that is configured to process batches that include a plurality of substrates at the same time. In some embodiments, the batch processing may include a rotatable stage on which the substrates are supported. The stage may rotate the substrates through different zones of the chamber in order to undergo one or both of a fluorination treatment and an organic acid soak. In some embodiments, purge regions may be provided between the fluorination treatment region and the organic acid soak region. Multiple rotations of the substrates within the chamber can be used to provide the desired number of cycles.

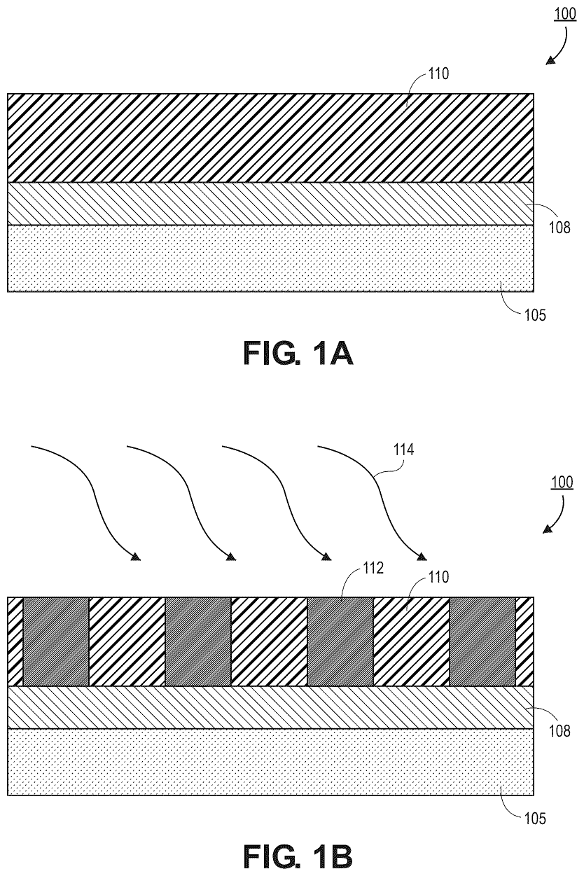

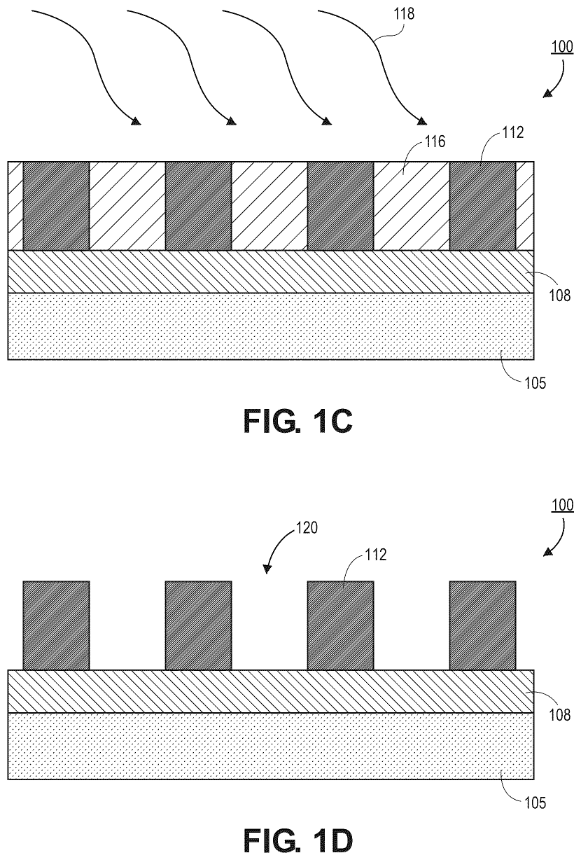

Referring now to FIG. 1A-1D, a series of cross-sectional illustrations depicting a process for patterning a resist layer 110 on a device 100 is shown, in accordance with an embodiment.

Referring now to FIG. 1A, a cross-sectional illustration of a portion of the device 100 is shown, in accordance with an embodiment. In an embodiment, the device 100 may comprise a patterning stack 105 that is provided over an underlying substrate (not shown). The substrate may comprise a semiconductor material, such as a silicon wafer, an oxide layer, a nitride layer, a metallic layer, or the like. In an embodiment, the patterning stack 105 may comprise one or more layers suitable for transferring a pattern formed into the resist layer 110 into the underlying substrate. While shown as a single layer, the patterning stack 105 may comprise multiple layers, such as a silicon hardmask layer, a carbon hardmask layer, an antireflective coating, and/or the like.

In an embodiment, an underlayer 108 may be provided between the resist layer 110 and the patterning stack 105. In some embodiments, the underlayer 108 may be considered as part of the patterning stack 105, despite being shown as a distinct layer. In an embodiment, the underlayer 108 may comprise a chemical structure that is also reactive to the DUV and/or EUV radiation in order to generate species that can diffuse into the resist layer 110 in order to help drive the chemical reaction within the resist layer 110 that leads to the solubility switch.

In an embodiment, the resist layer 110 may include any suitable photoresist material that is compatible with DUV and/or EUV lithography. In a particular embodiment, the resist layer 110 is a MOR material, such as any of the MOR materials and/or organometallic oxide materials described in greater detail herein.

Referring now to FIG. 1B, a cross-sectional illustration of the portion of the device 100 after an exposure process is shown, in accordance with an embodiment. In an embodiment, the exposure process may result in the formation of a latent image 112 in the resist layer 110. The exposure process may include an EUV exposure, a DUV exposure, or the like. FIG. 1B also illustrates a treatment 114 that is applied to the resist layer 110 after the exposure. In some embodiments, the treatment 114 is optional. For example, the treatment may include a fluorination treatment, such as exposure to one or more of hydrogen fluoride, ammonium fluoride, sulfur hexafluoride, nitrogen trifluoride, xenon difluoride, or the like. In other embodiments, the treatment 114 may comprise a sulfurization treatment, such as exposure to one or more of hydrogen sulfide, sulfur dioxide, carbon disulfide, or sulfur hexafluoride. The treatment 114 may also comprise both sulfur and fluorine in some embodiments.

Referring now to FIG. 1C, a cross-sectional illustration of the portion of the device 100 is shown, in accordance with an embodiment. As shown, the resist layer 110 has been converted into a treated resist layer 116 by the treatment 114. That is, fluorine and/or sulfur may be incorporated into the surfaces of the treated resist layer 116 in some embodiments. In an embodiment, FIG. 1C also illustrates the exposure to a processing gas 118. The processing gas 118 may include a gas suitable for etching the treated resist layer 116.

In an embodiment, the processing gas 118 may comprise an organic acid that comprises one or more of acetic acid, formic acid, propanoic acid, lactic acid, oxalic acid, trifluoroacetic acid, difluoroacetic acid, monofluoroacetic acid, trichloroacetic acid, tribromoacetic acid, triiodoacetic acid, any isomers thereof, or the like. The processing gas may also comprise a ketone, such as acetylacetone, hexafluoroacetone, or the like. In an embodiment, the organic acid and/or ketone may be applied in a chamber with a pressure between approximately 0.1 Torr and 100 Torr. The duration of the dry etching process with the processing gas may comprise exposing the device 100 to the processing gas for up to approximately 0.5 minutes, up to approximately 1.0 minute, up to approximately 5.0 minutes, up to approximately 6.0 minutes or more, up to approximately 7.0 minutes or more, up to approximately 8.0 minutes or more, up to approximately 9.0 minutes or more, up to approximately 10 minutes or more, approximately 30 minutes or more, approximately 1.0 hours or more, or approximately 2.0 hours or more. Though, longer exposures to the processing gas may also be used in some embodiments. In some embodiments, the exposure time may be between 1.0 seconds and 10 minutes, between 5.0 minutes and 10 minutes, between 10 minutes and 2.0 hours, between 10 minutes and 1.0 hours, between 10 minutes and 45 minutes, between 10 minutes and 30 minutes, or between 10 minutes and 15 minutes. Though, exposure times within a duration of any subset the listed ranges herein may also be used in some embodiments. A temperature of the device 100 during the exposure to the organic acid may be between approximately 50° C. and approximately 400° C., between approximately 100° C. and approximately 250° C., or between approximately 80° C. and 110° C.

Referring now to FIG. 1D a cross-sectional illustration of the portion of the device 100 after the treated resist layer 116 is fully removed is shown, in accordance with an embodiment. As shown, the treated resist layer is removed to form a pattern in the resist layer 110 that includes the latent image 112. For example, openings 120 (e.g., trenches, holes, etc.) may be formed through a thickness of the resist layer 110 in order to define the desired pattern. The pattern of the openings 120 may then be transferred into underlying layers (e.g., the underlayer 108, the patterning stack 105, an underlying substrate, etc.) with subsequent etching processes.

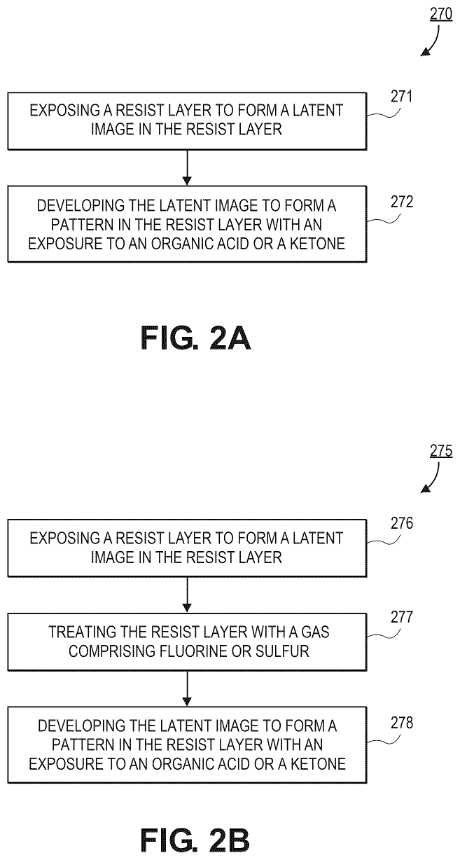

Referring now to FIG. 2A, a flow diagram that depicts a process 270 for patterning a resist layer is shown, in accordance with an embodiment. In an embodiment, the process 270 may begin with operation 271, which comprises exposing a resist layer to form a latent image in the resist layer. The exposure process may include an EUV exposure, a DUV exposure, or the like. The resist layer may comprise a MOR or any other suitable resist material, such as those described in greater detail herein.

In an embodiment, the process 270 may continue with operation 272, which comprises developing the latent image to form a patten in the resist layer with an exposure to an organic acid and/or a ketone. For example, developing the latent image may include removing portions of the resist layer that were not exposed during operation 271. That is, the latent image may persist after the developing process. In an embodiment, the organic acid and/or ketone may be part of a processing gas is that is provided over the resist layer. The organic acid may include any of the organic acids described in greater detail herein, such as an acetic acid or the like, and the ketone may include any of the ketones described herein.

In an embodiment, the organic acid and/or keystone may be applied to the resist layer in a chamber with a pressure between approximately 0.1 Torr and 100 Torr. The duration of the dry etching process with the processing gas may comprise exposing the device 100 to the processing gas for up to approximately 0.5 minutes, up to approximately 1.0 minute, up to approximately 5.0 minutes, up to approximately 6.0 minutes or more, up to approximately 7.0 minutes or more, up to approximately 8.0 minutes or more, up to approximately 9.0 minutes or more, up to approximately 10 minutes or more, approximately 30 minutes or more, approximately 1.0 hours or more, or approximately 2.0 hours or more. Though, longer exposures to the processing gas may also be used in some embodiments. In some embodiments, the exposure time may be between 1.0 seconds and 10 minutes, between 5.0 minutes and 10 minutes, between 10 minutes and 2.0 hours, between 10 minutes and 1.0 hours, between 10 minutes and 45 minutes, between 10 minutes and 30 minutes, or between 10 minutes and 15 minutes. Though, exposure times within a duration of any subset the listed ranges herein may also be used in some embodiments. A temperature of the device 100 during the exposure to the organic acid and/or ketone may be between approximately 50° C. and approximately 400° C., between approximately 100° C. and approximately 250° C., or between approximately 80° C. and 110° C.

In some embodiments, the operation 272 may be followed by a purging operation. The purging operation may include flowing an inert gas into the chamber in order to remove volatile byproducts and/or the like. In some embodiments, operations 272 and the purging operation may be repeated a plurality of times (e.g., 2 or more times, 5 or more times, 50 or more times, or 100 or more times).

Referring now to FIG. 2B, a flow diagram of a process 275 for developing a resist layer with a dry deposition process is shown, in accordance with an additional embodiment. In an embodiment, the process 275 may begin with operation 276, which comprises exposing a resist layer to form a latent image in the resist layer. The exposure process may include an EUV exposure, a DUV exposure, or the like. The resist layer may comprise a MOR or any other suitable resist material, such as those described in greater detail herein.

In an embodiment, the process 275 may continue with operation 277, which comprises treating the resist layer with a gas comprising one or both of fluorine or sulfur. In an embodiment, the treatment gas may comprise any suitable fluorine comprising gas and/or sulfur comprising gas, such as those described in greater detail herein. The fluorine and/or sulfur may be incorporated into the resist layer in order to improve the selectivity of the development between the latent image and the unexposed regions of the resist layer in subsequent processing operations.

In an embodiment, the process 275 may continue with operation 278, which comprises developing the latent image to form a patten in the resist layer with an exposure to an organic acid and/or ketone. For example, developing the latent image may include removing portions of the resist layer that were not exposed during operation 276. That is, the latent image may persist after the developing process. In an embodiment, the organic acid and/or ketone may be part of a processing gas is that is provided over the resist layer. The organic acid may include any of the organic acids described in greater detail herein, such as an acetic acid or the like. The ketone may include any of the ketones described in greater detail herein.

In an embodiment, operations 277 and 278 may be applied to the resist layer in a chamber with a pressure between approximately 0.1 Torr and 100 Torr. The duration of the treatment and/or dry etching process with the processing gas may comprise exposing the device 100 to the processing gas for up to approximately 0.5 minutes, up to approximately 1.0 minute, up to approximately 5.0 minutes, up to approximately 6.0 minutes or more, up to approximately 7.0 minutes or more, up to approximately 8.0 minutes or more, up to approximately 9.0 minutes or more, up to approximately 10 minutes or more, approximately 30 minutes or more, approximately 1.0 hours or more, or approximately 2.0 hours or more. Though, longer exposures to the processing gas may also be used in some embodiments. In some embodiments, the exposure time may be between 1.0 seconds and 10 minutes, between 5.0 minutes and 10 minutes, between 10 minutes and 2.0 hours, between 10 minutes and 1.0 hours, between 10 minutes and 45 minutes, between 10 minutes and 30 minutes, or between 10 minutes and 15 minutes. Though, exposure times within a duration of any subset the listed ranges herein may also be used in some embodiments. A temperature of the device 100 during the exposure to the organic acid may be between approximately 50° C. and approximately 400° C., between approximately 100° C. and approximately 250° C., or between approximately 80° C. and 110° C.

In some embodiments, operations 277 and 278 may be repeated a plurality of times (e.g., 2 or more times, 5 or more times, 50 or more times, or 100 or more times). The operations 277 and 278 may also be separated from each other by a purging operations. For example, an inert gas may be flown into the chamber between the treatment operation 277 and the developing operation 278 in some embodiments.

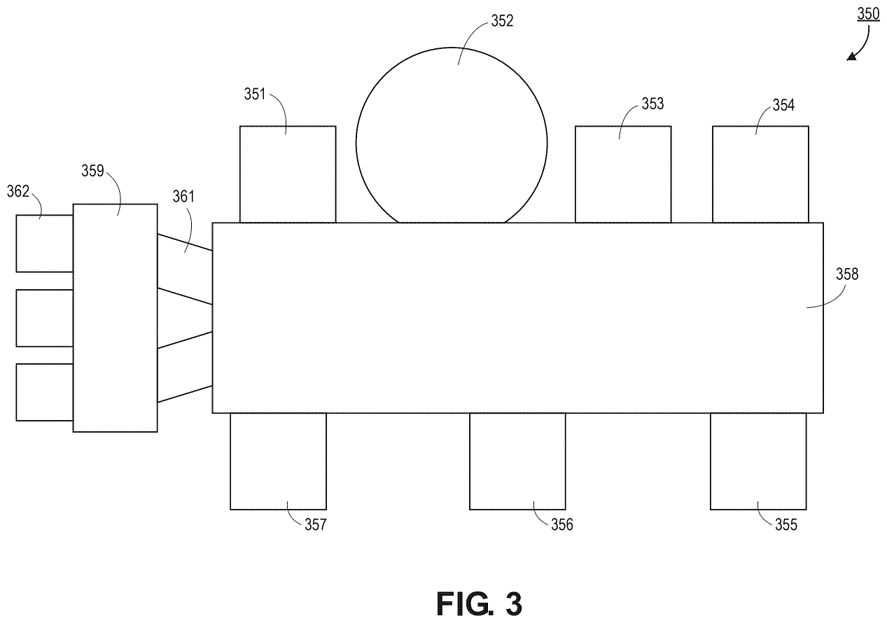

As noted above, the developing process for the exposed resist layer may be a relatively long process due to long exposures to the organic acid, and/or due to a large number of cycles of the process. Accordingly, embodiments disclosed herein may include a batch processing tool in order to develop the resist layers on a plurality of substrates substantially in parallel. As used herein, “substantially in parallel” may refer to two substrates that are being processed at the same time within the same tool. In some instances, “substantially in parallel” may refer to a first substrate and a second substrate in a single chamber, where the first substrate is in a first region of a chamber (and exposed to a first gas and/or processing condition), and the second substrate is in a second region of the chamber (and exposed to a second gas and/or environmental condition). Though, “substantially in parallel” may also refer to a pair of substrates being within the same chamber and within the same region (of a multi-region chamber) for at least some duration of the processing of the pair of substrates. An example of such an embodiment is shown in FIG. 3.

Referring now to FIG. 3, a plan view schematic illustration of a processing tool 350 is shown, in accordance with an embodiment. In an embodiment, the processing tool 350 may be a cluster tool that comprises a plurality of different chambers and/or stations for implementing various portions of a dry develop process. For example, the processing tool 350 may comprise a factory interface 359 that is configured to receive one or more front opening unified pods (FOUPS) 362. In an embodiment, the FOUPs 362 may be used to deliver substrates to the processing tool 350 and/or transport substrates from the processing tool 350. In an embodiment, the factory interface 359 is coupled to a transfer chamber 358 by one or more load locks 361.

In an embodiment, a first chamber 351 is coupled to the transfer chamber 358. In an embodiment, the first chamber 351 may comprise a batch oven. The batch oven may be used to perform a post exposure bake (PEB) in order to improve the cross-linking in the exposed area of the resist. The PEB may be implemented in conjunction with the flow of an inert gas (e.g., argon, nitrogen, helium, etc.) or in the presence of an active gas (e.g. NH₃, H₂, O₂, H₂O, H₂S, etc.). The first chamber 351 may have a capacity suitable for processing 1 or more substrates, 5 or more substrates, or 25 or more substrates.

In an embodiment, a second chamber 352 may comprise a dry develop chamber. In an embodiment, the dry develop chamber may be a chamber that is suitable for flowing treatment gasses, processing gasses, inert gasses, and/or the like in order to implement processes such as process 270 and/or process 275 described in greater detail herein. The second chamber 352 may be capable of supporting sub-atmospheric pressures (e.g., between approximately 0.1 Torr and approximately 100 Torr) in some embodiments. For example, the second chamber 352 may comprise an exhaust line that is fluidly coupled to a vacuum pump in order to pump down the chamber to a sub-atmospheric pressure and/or to remove volatile byproducts and/or the like from the second chamber 352.

In an embodiment, the second chamber 352 may be suitable for batch processing a plurality of substrates in order to improve the throughput of the processing tool 350. In some embodiments, the second chamber 352 may include a rotating stage that allows the substrates to be rotated through different regions of the second chamber 352 in order to implement treatment processes, dry development processes, purging processes, and/or the like. In some embodiments, the second chamber may also comprise a residual gas analyzer (RGA) in order to detect byproduct concentrations (e.g., tin byproducts from MOR developing). Such byproduct concentration detection may be used to implement end point tracking in order to determine when the development process is fully completed. More detailed descriptions of the second chamber 352 are provided in greater detail herein.

In an embodiment, the processing tool 350 may further comprise a third chamber 353. In an embodiment, the third chamber 353 may comprise an etching chamber that is used to provide descumming operations. Descumming operations may be used to fully clear openings from the pattern formed in the resist layer. This can be used to improve the profile of the openings and enables better pattern transfer into the underlying layers.

In an embodiment, the processing tool 350 may further comprise a fourth chamber 354 that functions as a post development treatment chamber. For example, the treatment chamber may provide the ability to flow one or more post development treatment gasses over the resist layer in order to densify the resist layer or the like. For example, post development treatment gasses may comprise one or more of H₂S, H₂O, NH₃, O₂, H₂O₂, O₃, or the like. Pressures within the fourth chamber 354 may be between approximately 0.1 Torr and approximately 100 Torr, and temperatures may be maintained between approximately 50° C. and approximately 500° C., between approximately 100° C. and approximately 250° C., or between approximately 80° C. and 110° C. in some embodiments.

In an embodiment, the processing tool 350 may further comprise a fifth chamber 355 that is used to transfer a pattern in the resist layer into an underlayer. In an embodiment, the fifth chamber 355 may comprise an etching chamber, such as a plasma etching chamber or the like.

In an embodiment, the processing tool 350 may further comprise a sixth chamber 356 that is used to strip the resist layer after the underlayer is patterned. The sixth chamber 356 may comprise a plasma etching chamber in some embodiments.

In an embodiment, the processing tool 350 may further comprise a seventh chamber 357 that is used to remove the underlayer. For example, a plasma etching chamber suitable for removing carbon based underlayers may be used in some embodiments.

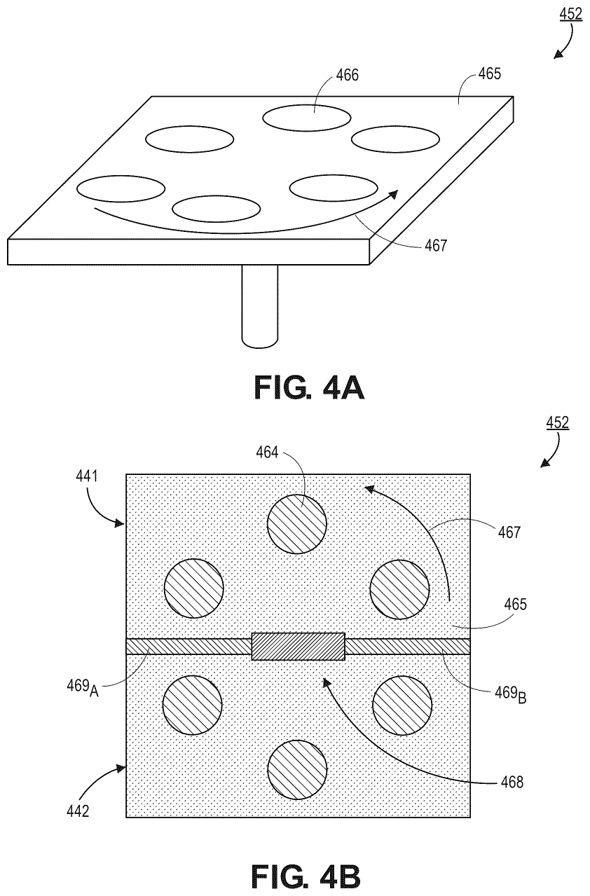

Referring now to FIG. 4A, a perspective view illustration of a portion of a dry develop chamber 452 is shown, in accordance with an embodiment. As shown, a stage 465 may be provided in the dry develop chamber 452. The chamber walls and other details of the dry develop chamber 452 are omitted from FIG. 4A for simplicity. In an embodiment, the stage 465 may comprise a plurality of positions 466 that are suitable for retaining substrates (not shown). The positions 466 may be rotated (as indicated by arrow 467). The rotation of the positions 466 allows for the substrates to be rotated through different regions of the dry develop chamber 452 (e.g., to undergo different processing operations within a single chamber).

Referring now to FIG. 4B, a plan view illustration of the dry develop chamber 452 is shown, in accordance with an embodiment. In an embodiment, the dry develop chamber 452 may be separated into a first region 441 and a second region 442 by a separator 468. In the embodiment shown in FIG. 4B, the separator 468 comprises a pair of doors 469_{A} and 469_{B} that open to allow rotation 467 of the substrate 464 between the first region 441 and the second region 442. The doors 469_{A} and 469_{B} can then be closed in order to implement the different processing operations and/or treatments in the first region 441 and the second region 442. That is, the substrates 464 may be rotated between processing operations and/or treatments.

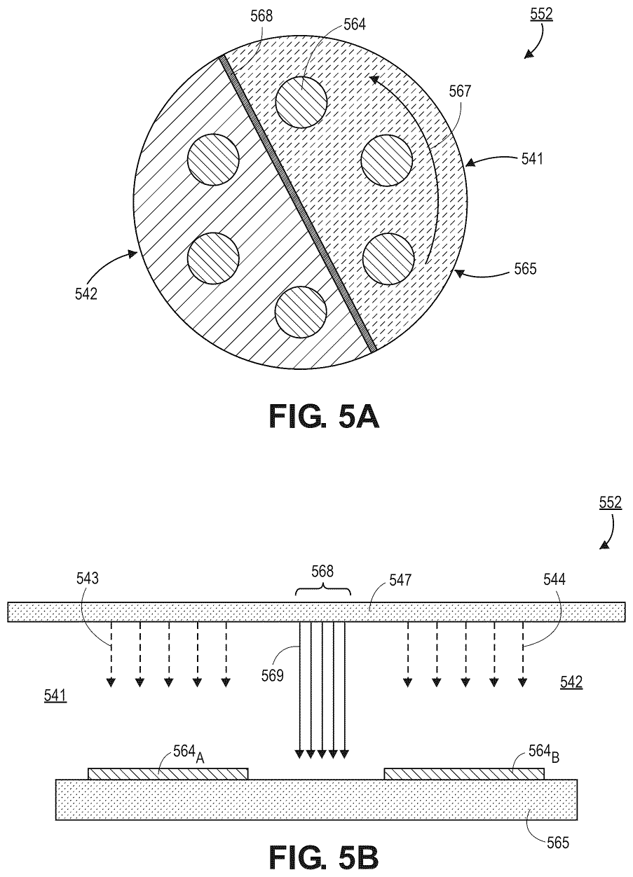

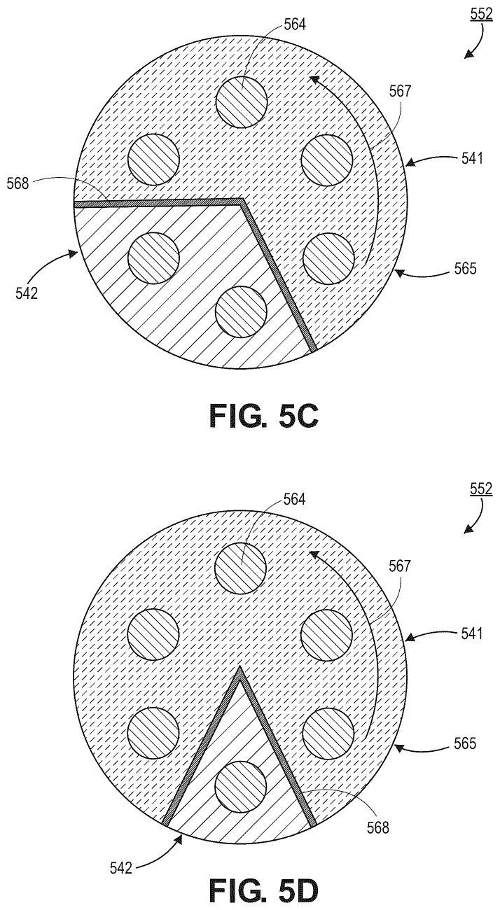

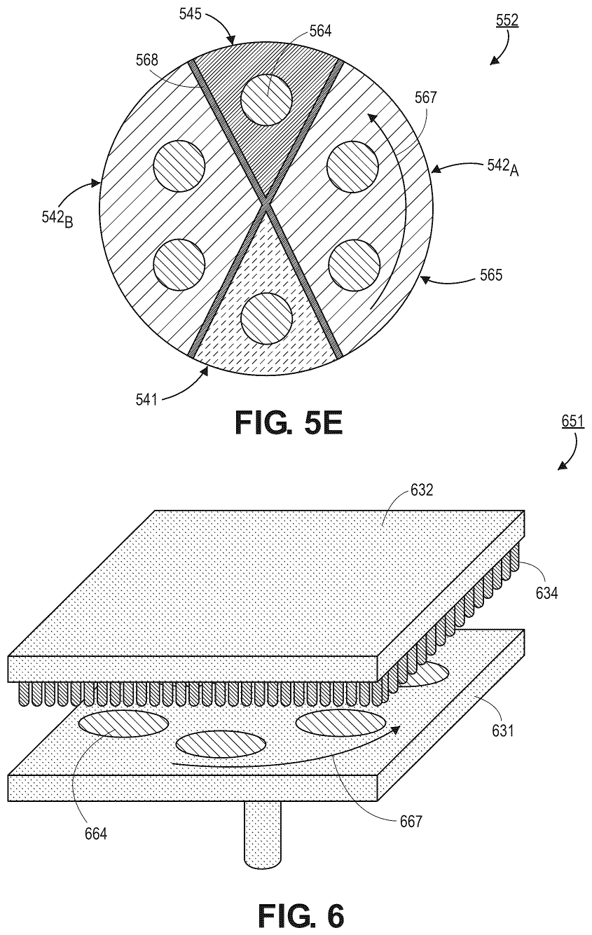

Referring now to FIG. 5A-5E, a series of illustrations depicting dry develop chambers 552 in accordance with additional embodiments is shown, in accordance with various embodiments. In FIG. 5A-5E, the stage 565 may be rotated during the processing operations and/or treatments. That is, each region of the dry develop chamber 552 may continuously operate, and the substrates 564 are rotated 567 through the different regions of the dry develop chamber 552. In this way, dry develop processes described herein (e.g., process 270 and/or process 275) may be implemented in a batch processing fashion in order to increase throughput.

Referring now to FIG. 5A, a plan view illustration of a dry develop chamber 552 is shown, in accordance with an embodiment. In an embodiment, the dry develop chamber 552 may comprise a plurality of substrates 564 that are rotated on a stage 565. In an embodiment, the dry develop chamber 552 may comprise a first region 541 and a second region 542. The first region 541 and the second region 542 may be separated from each other by a gas curtain 568.

As shown in the cross-sectional illustration in FIG. 5B, the separator 568 flows an inert gas to form a gas curtain 569 from a lid 547 towards the stage 565 between the first region 541 and the second region 542. For example, the gas separator 568 may comprise a gas delivery structure, such as an opening, a nozzle, a showerhead structure, or the like, that is configured to flow and/or inject a gas (e.g., an inert gas) into the chamber in order to form the gas curtain 569. The flow of the inert gas to form the gas curtain 569 is sufficient to substantially segregate a first processing gas 543 flown in the first region 541 from a second processing gas 544 that is flown in the second region 542. As such, substrate 564_{A} may undergo a first processing operation, while substrate 564_{B} may undergo a different second processing operation. For example, the first processing operation may be a dry develop process where the first processing gas 543 comprises an organic acid and/or a ketone, such as an acetic acid, and the second processing operation may be a purge region where the second processing gas 544 comprises an inert gas. In some embodiments, a remote plasma source may be coupled to one or both of the first region 541 and/or the second region 542. An RGA may also be included in the dry develop chamber 552 to help with real time monitoring for endpoint detection.

As shown in FIG. 5A, the first region 541 and the second region 542 may comprise substantially the same area. That is, the gas curtain 568 may split the chamber 552 in half. In such an embodiment, a constant rotation speed for the stage 565 allows for cycling substrates 564 through a first processing operation in the first region 541 and a second processing operation in the second region 541 so that a duration of the first processing operation is substantially equal to a duration of the second processing operation.

In the illustrated embodiment, the dry develop chamber 552 comprises space to rotate six substrates 564. Though, it is to be appreciated that the dry develop chamber 552 may be sized to accommodate any number of substrates 564. For example, the dry develop chamber 552 may rotate 10 or more substrates 564 or 20 or more substrates 564 in some embodiments.

Referring now to FIG. 5C, a plan view illustration of a dry develop chamber 552 is shown, in accordance with an additional embodiment. In an embodiment, the dry develop chamber 552 in FIG. 5C may be similar to the dry develop chamber 552 in FIG. 5A, with the exception of the division between the first region 541 and the second region 542. For example, the dry develop chamber 552 in FIG. 5C may include a first region 541 that is larger in area than the second region 542. In the particular embodiment shown in FIG. 5C, the first region 541 is twice as large as the second region 542. As such, the substrates 564 will spend twice as long being processed with the first process and/or treatment compared to the second process and/or treatment.

Referring now FIG. 5D, a plan view illustration of a dry develop chamber 552 is shown, in accordance with an additional embodiment. In an embodiment, the dry develop chamber 552 in FIG. 5D may be similar to the dry develop chamber 552 in FIG. 5A, with the exception of the division between the first region 541 and the second region 542. For example, the dry develop chamber 552 in FIG. 5D may include a first region 541 that is larger in area than the second region 542. In the particular embodiment shown in FIG. 5D, the first region 541 is five times as large as the second region 542. As such, the substrates 564 will spend five times as long being processed with the first process and/or treatment compared to the second process and/or treatment.

Referring now to FIG. 5E, a plan view illustration of a dry develop chamber 552 is shown, in accordance with an additional embodiment. In an embodiment, the dry develop chamber 552 may comprise a plurality of regions in order to implement a plurality of different processing operations. For example, a first region 541 may be separated from a third region 545 by second regions 542_{A} and 542_{B}. For example, the dry develop chamber 552 may be used to implement a process similar to process 275 described in greater detail herein. That is, the treatment operation 277 may be implemented in the third region 545, and the dry develop operation 278 may be implemented in the first region 541. Purge regions 542_{A} and 542_{B} may be provided between the first region 541 and the third region 545. Rotating the substrates 564 through the different regions may allow for cycling the process 275 a plurality of times.

Referring now to FIG. 6, a perspective view illustration of a batch oven 651 is shown, in accordance with an embodiment. The batch oven 651 may be incorporated into the processing tool 350 (e.g., as the first chamber 351) in order to implement a PEB on a plurality of substrates 664. In an embodiment, the batch oven 651 may comprise a pedestal 631 that rotates 667 the substrates 664. A lid 632 may comprise a plurality of lamps 634 in order to heat the substrates 664. Gas may be flown between the lid 632 and the pedestal 631 in some embodiments.

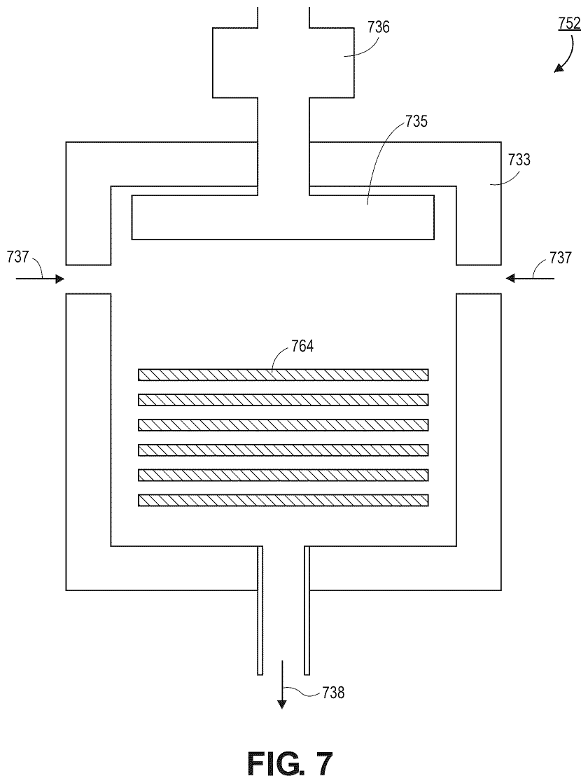

Referring now to FIG. 7, a dry develop chamber 752 is shown, in accordance with an additional embodiment. In an embodiment, the dry develop chamber 752 in FIG. 7 allows for developing a plurality of substrates 764 with a batch process. However, instead of rotating the substrate 764 (e.g., similar to dry develop chamber 552), the substrates 764 are vertically stacked within a chamber housing 733. A showerhead 735 at the top of the chamber housing 733 may be coupled to a remote plasma source 736 in order to allow for plasma generation within the chamber housing 733. In an embodiment gas 737 may be flown into the chamber housing 733 in order to implement one or both of a fluorination treatment process and the organic acid/ketone dry develop process. A purge line 738 may be coupled to a pump (not shown). In an embodiment, the dry develop chamber 752 may also comprise an RGA to help with real time monitoring for endpoint detection.

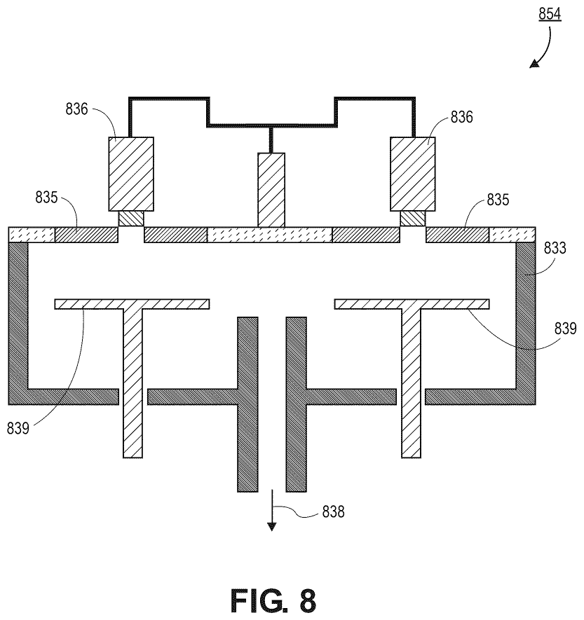

Referring now to FIG. 8, a cross-sectional illustration of a chamber 854 that functions as a post development treatment chamber is shown, in accordance with an embodiment. In an embodiment, the chamber 854 may be similar to the chamber 354 that is part of the processing tool 350 described in greater detail herein. In an embodiment, the treatment chamber may provide the ability to flow one or more post development treatment gasses over the resist layer in order to densify the resist layer or the like. For example, post development treatment gasses may comprise one or more of H₂S, H₂O, NH₃, O₂, H₂O₂, O₃, or the like. Pressures within the fourth chamber 354 may be between approximately 0.1 Torr and approximately 100 Torr, and temperatures may be maintained between approximately 50° C. and approximately 500° C., between approximately 100° C. and approximately 250° C., or between approximately 80° C. and 110° C. in some embodiments.

In an embodiment, the chamber 854 may comprise one or more remote plasma sources 836 that are provided over heated pedestals 839 used to support substrates with developed resist layers. In an embodiment, plasma may be generated between showerheads 835 and the heated pedestals 839 within the chamber housing 833. The plasma treatment may result in the densification of the resist layers in order to improve pattern transfer performance (e.g., increased etch selectivity, reduced LER, and/or the like). In an embodiment, a pump (not shown) may be coupled to an exhaust line 838 of the chamber 854. As shown, two heated pedestals 839 are included in the chamber 854 in order to enhance throughput. It is to be appreciated that the chamber 854 may be designed and sized to accommodate any number of substrates in parallel.

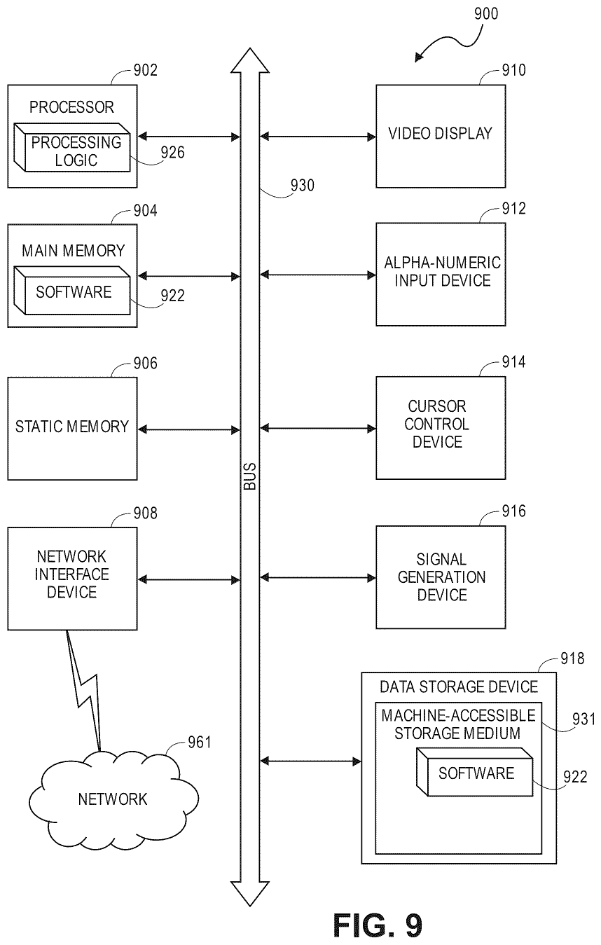

Referring now to FIG. 9, a block diagram of an exemplary computer system 900 of a processing tool is illustrated in accordance with an embodiment. In an embodiment, computer system 900 is coupled to and controls processing in the processing tool. Computer system 900 may be connected (e.g., networked) to other machines in a Local Area Network (LAN), an intranet, an extranet, or the Internet. Computer system 900 may operate in the capacity of a server or a client machine in a client-server network environment, or as a peer machine in a peer-to-peer (or distributed) network environment. Computer system 900 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 900, the term “machine” shall also be taken to include any collection of machines (e.g., computers) that individually or jointly execute a set (or multiple sets) of instructions to perform any one or more of the methodologies described herein.

Computer system 900 may include a computer program product, or software 922, having a non-transitory machine-readable medium having stored thereon instructions, which may be used to program computer system 900 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 900 includes a system processor 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), etc.), and a secondary memory 918 (e.g., a data storage device), which communicate with each other via a bus 930.

System processor 902 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 902 may also be one or more special-purpose processing devices such as an application specific integrated circuit (ASIC), a field programmable gate array (FPGA), a digital signal system processor (DSP), network system processor, or the like. System processor 902 is configured to execute the processing logic 926 for performing the operations described herein.

The computer system 900 may further include a system network interface device 908 for communicating with other devices or machines. The computer system 900 may also include a video display unit 910 (e.g., a liquid crystal display (LCD), a light emitting diode display (LED), or a cathode ray tube (CRT)), an alphanumeric input device 912 (e.g., a keyboard), a cursor control device 914 (e.g., a mouse), and a signal generation device 916 (e.g., a speaker).

The secondary memory 918 may include a machine-accessible storage medium 931 (or more specifically a computer-readable storage medium) on which is stored one or more sets of instructions (e.g., software 922) embodying any one or more of the methodologies or functions described herein. The software 922 may also reside, completely or at least partially, within the main memory 904 and/or within the system processor 902 during execution thereof by the computer system 900, the main memory 904 and the system processor 902 also constituting machine-readable storage media. The software 922 may further be transmitted or received over a network 961 via the system network interface device 908. In an embodiment, the network interface device 908 may operate using RF coupling, optical coupling, acoustic coupling, or inductive coupling.

While the machine-accessible storage medium 931 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method of developing a resist layer on a substrate that has been selectively exposed with a lithography process, the method comprising:
exposing the resist layer to a gas comprising one or both of an organic acid or a ketone in a chamber with an exposure time that is at least ten minutes, wherein the gas selectively removes an unexposed portion of the resist layer to form a pattern in the resist layer, and wherein the resist layer comprises a metal; and
purging the chamber.

2. The method of claim 1, wherein the organic acid comprises one or more of acetic acid, formic acid, propanoic acid, lactic acid, oxalic acid, trifluoroacetic acid, difluoroacetic acid, monofluoroacetic acid, trichloroacetic acid, tribromoacetic acid, triiodoacetic acid, or any isomers thereof, and wherein the ketone comprises one or both of acetylacetone or hexafluoroacetone.

3. The method of claim 1, wherein the exposure time is between approximately 30 minutes and approximately 2 hours before purging the chamber.

4. The method of claim 1, further comprising:
repeating the operations of exposing the resist layer to the gas comprising the organic acid and/or the ketone and purging the chamber a plurality of times.

5. The method of claim 4, wherein the plurality of times is up to 100 times.

6. The method of claim 1, wherein the resist layer is maintained at a temperature between approximately 50° C. and approximately 400° C. during exposing the resist layer to the gas comprising the organic acid and/or the ketone.

7. The method of claim 6, wherein the temperature is between approximately 100° C. and approximately 250° C. during exposing the resist layer to the gas comprising the organic acid and/or the ketone.

8. The method of claim 1, wherein the chamber is maintained at a pressure between approximately 0.1 Torr and approximately 100 Torr during exposing the resist layer to the gas comprising the organic acid and/or the ketone.

9. The method of claim 1, further comprising:
treating the resist layer with a treatment gas that comprises one or both of fluorine or sulfur.

10. The method of claim 9, wherein the treatment gas comprises one or more of hydrogen fluoride, ammonium fluoride, sulfur hexafluoride, nitrogen trifluoride, or xenon difluoride, hydrogen sulfide, sulfur dioxide, or carbon disulfide.

11. The method of claim 1, wherein the substrate is rotated through a first region of the chamber during the operation of exposing the resist layer to the gas comprising the organic acid and/or the ketone, and rotated through a second region of the chamber during the operation of purging the chamber.

12. A method, comprising:
rotating a substrate through a chamber comprising a first region and a second region, wherein the substrate comprises a resist layer with a latent image produced by exposure to extreme ultraviolet (EUV) radiation;
exposing the resist layer to a processing gas that comprises an organic acid and/or a ketone in the first region of the chamber; and
exposing the resist layer to an inert gas in the second region of the chamber.

13. The method of claim 12, wherein the substrate remains in the first region of the chamber for a longer duration than the second region of the chamber.

14. The method of claim 12, wherein the substrate is rotated through the first region of the chamber and the second region of the chamber a plurality of times.

15. The method of claim 12, wherein the first region of the chamber is separated from the second region of the chamber by a gas curtain.

16. The method of claim 12, further comprising:
rotating the substrate through a third region of the chamber, wherein the second region of the chamber is between the first region of the chamber and the third region of the chamber, and wherein the resist layer is exposed to a treatment gas that comprises one or both of fluorine or sulfur in the third region of the chamber.

17. The method of claim 16, further comprising:
rotating the substrate through a fourth region of the chamber, wherein the substrate is exposed to an inert gas in the fourth region of the chamber.

18. The method of claim 17, wherein the substrate is rotated through the third region before being rotated through the second region, wherein the substrate is rotated through the second region before being rotated through the first region, and wherein the substrate is rotated through the first region before being rotated through the fourth region.

19. The method of claim 16, wherein the substrate resides within the first region for at least 10 minutes during the method, and wherein the substrate resides in the third region for at least 10 minutes during the method.

20. The method of claim 12, further comprising:
rotating a second substrate through the chamber, wherein the second substrate comprises a second resist layer with a second latent image produced by exposure to EUV radiation, and wherein the substrate and the second substrate are processed substantially in parallel within the chamber.
